(19) United States
(12) Patent Application Publication
(10) Pub. No.: US 2014/0197017 A1
(43) Pub. Date: Jul. 17, 2014

(54) TOUCH PANEL STRUCTURE AND FABRICATION METHOD THEREOF

(71) Applicants: WINTEK (CHINA) TECHNOLOGY LTD., Dongguan City (CN); WINTEK CORPORATION, Taichung City (TW)

(72) Inventors: Chih-Hsien Lien, Taichung City (TW); Peng-Chih Yu, Taichung City (TW); Su-Ming Lin, Taichung City (TW); Ping-Wen Huang, Taichung City (TW)

(73) Assignees: WINTEK CORPORATION, Taichung City (TW); WINTEK (CHINA) TECHNOLOGY LTD., Dongguan City (CN)

(21) Appl. No.: 13/742,364

(22) Filed: Jan. 16, 2013

(51) Int. Cl. H03K 17/96

(52) U.S. Cl. CPC H03K 17/962
USPC 200/600; 427/108

(57) ABSTRACT

A touch panel structure and a fabrication method thereof. The touch panel structure includes a substrate, a decoration layer, a touch unit and at least one first ink layer. The decoration layer and the touch unit are disposed on a side of the substrate, wherein the decoration layer is sandwiched between the touch unit and the substrate. The decoration layer includes a display region and at least one pattern disposition region, and the touch unit includes a transparent sensing unit extending over the pattern disposition region. The first ink layer is disposed on the touch unit and includes at least one pattern. The first ink layer corresponds to the pattern disposition region. The touch panel structure and related fabrication method have low cost and low productive hours.

### BACKGROUND OF THE INVENTION

1. Field of the Invention

The present invention is related to a touch panel structure and a fabrication method thereof, and more particularly, to a touch panel structure with a delaminated structure and fabrication method thereof with related process for forming the pattern of the touch panel, so as to reduce the fabrication cost and total productive hours.

2. Description of the Prior Art

Referring to FIG. 1 and FIG. 2, FIG. 1 and FIG. 2 are schematic diagrams of a prior-art touch panel structure. The conventional touch panel 10 includes a substrate 11, and an isolation layer 12 disposed on a side of the substrate 11. The isolation layer 12 can be made of silicon dioxide (SiO₂). The substrate 11 and the isolation layer 12 are both made of transparent materials. A touch unit 13 is disposed on a side of the isolation layer 12 opposite to the substrate 11. The touch unit 13 includes a transparent sensing unit 131 and a wiring 132. A decoration layer 14 is disposed between the touch unit 13 and the isolation layer 12. The decoration layer 14 has an opaque material and is mostly black. For example, black resin may be adopted as the material of the decoration layer 14. The decoration layer 14 is disposed around the isolation layer 12 with a rectangular shape (shown as the hatched region in FIG. 1), in order to cover the wiring 132 of the touch unit 13. A transparent sensing unit 131 is disposed inside the region surrounded by the decoration layer 14 to forma touch region. Usually, the conventional touch panel 10 has a product/company trademark or an icon to provide operation instructions for users. Currently, the pattern-like elements are mostly formed through a photomask process. Taking the pattern 15 in FIG. 1 as an example, a circular region is formed on the decoration layer 14 through the photomask formation process, and then the touch unit 13 is disposed on the side of the decoration layer 14 opposite to the isolation layer 12. After that, the isolation layer 16 is further disposed on the side of the touch unit 13 opposite to the decoration layer 14, following by disposing an ink layer 17 on the side of the isolation layer 16 opposite to the touch unit 13. Generally, the ink layer 17 has a color different from the decoration layer 14 in order to emphasize pattern 15.

The conventional photomask formation process has a mainly disadvantage that different photomasks have to be manufactured when the patterns of the decoration layer are different, which takes much fabrication cost and productive hours and the production period of touch panel is increased.

### SUMMARY OF THE INVENTION

From the above-mentioned disadvantages of the prior-art touch panel, the present invention provides a touch panel structure and a fabrication method thereof by forming touch panel patterns by delaminated structure and related process, so as to reduce the fabrication cost and productive hours.

In order to achieve the above-mentioned objective, the present invention provides a touch panel structure, including:

a substrate, wherein the substrate is made of a transparent material;

a decoration layer, disposed on a side of the substrate, wherein the decoration layer has a display region and at least one pattern disposition region, and the decoration layer is made of an opaque material;

a touch unit, disposed on a side of the substrate and having a transparent sensing unit, wherein the decoration layer is sandwiched between the touch unit and the substrate; and

at least one first ink layer, disposed on the touch unit, wherein the first ink layer has at least one pattern, and the first ink layer corresponds to the pattern disposition region.

In order to achieve the above-mentioned objective, the present invention further provides a fabrication method of a touch panel structure, including:

disposing an opaque decoration layer on a side of a transparent substrate, wherein the decoration layer has a display region and at least one pattern disposition region;

disposing a touch unit on a side of the substrate, wherein the decoration layer is sandwiched between the touch unit and the substrate, and the touch unit includes a transparent sensing unit extending over the pattern disposition region; and

disposing at least one first ink layer on the touch unit, wherein the first ink layer has at least one pattern, and the first ink layer corresponds to the pattern disposition region.

To provide a further understanding of objective and effects of the present invention to the Examiner in the structure of the present invention, embodiments will be detailed as follows, accompanied with drawings.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a top view of the structure of a prior-art touch panel.

FIG. 2 is a sectional view along line A-A of the structure shown in FIG. 1.

FIG. 3 is a schematic diagram of a top view of the structure of a touch panel according to an embodiment of the present invention.

FIG. 4A is a sectional view along line B-B of the structure shown in FIG. 3.

FIG. 4B is a schematic sectional diagram of the structure of a touch panel according to another embodiment of the present invention.

FIG. 5 is a process flow chart of the fabrication method of a touch panel of the present invention.

FIG. 6 is a schematic diagram of the configuration structure of the first ink layer and the decoration layer shown in FIG. 3 according to one embodiment of the present invention.

FIG. 7 is a schematic diagram of the configuration structure of the first ink layer and the decoration layer with a modified relative location related to the embodiment shown in FIG. 3 of the present invention.

FIG. 8 and FIG. 9 are schematic diagrams of the configuration structure of the first ink layer and the decoration layer according to another embodiment of the present invention.

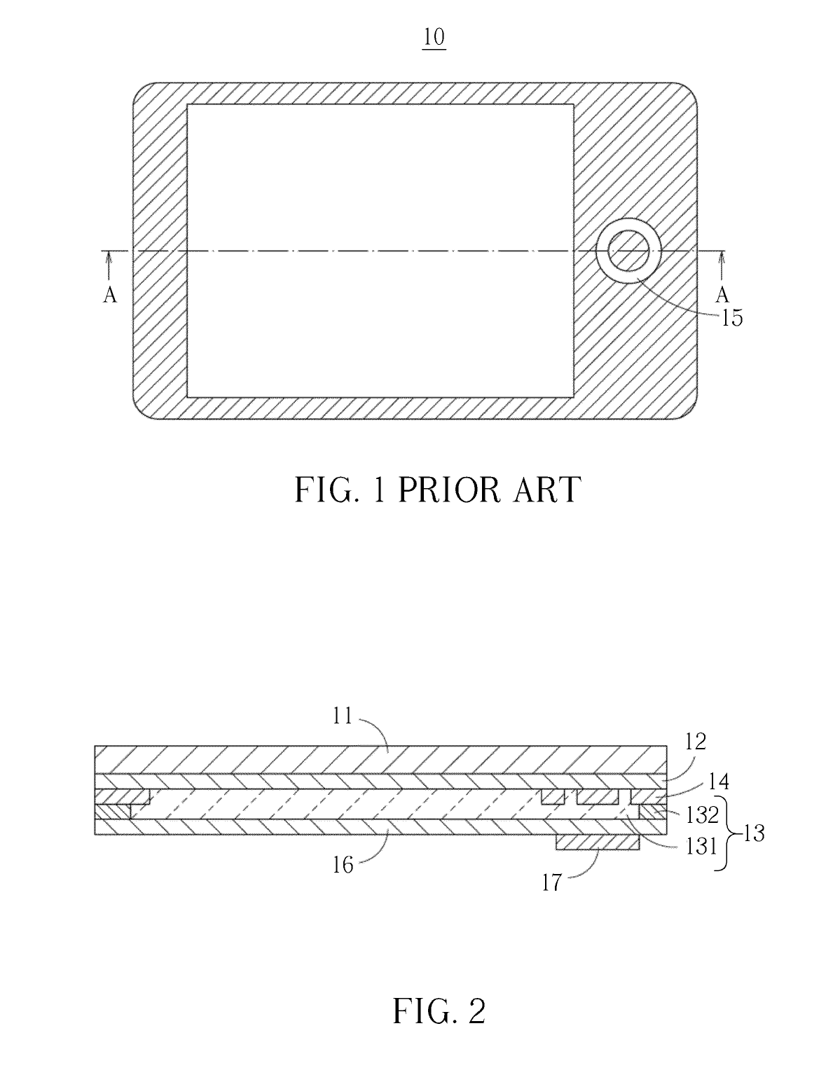

### DETAILED DESCRIPTION

The technology concept and effects for achieving the objective of the present invention will now be described with reference to the drawings and embodiments. The illustrated embodiments and drawings are intended to illustrate, but not to limit, the present invention.

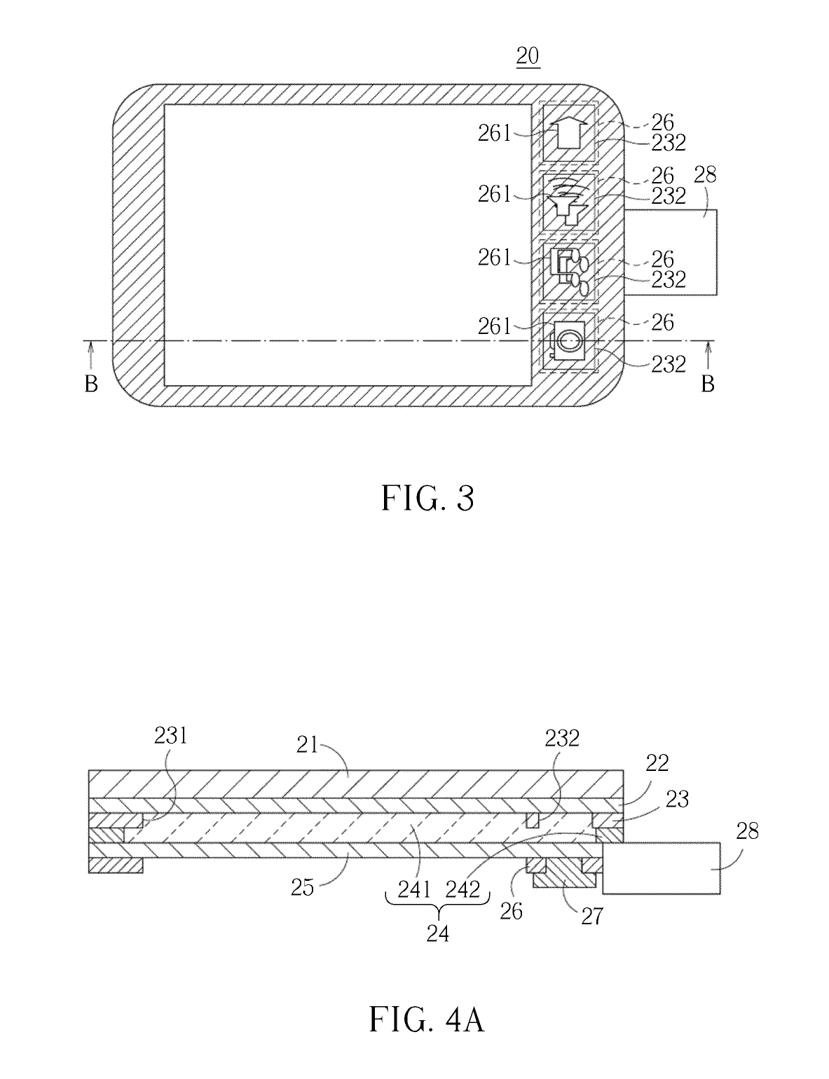

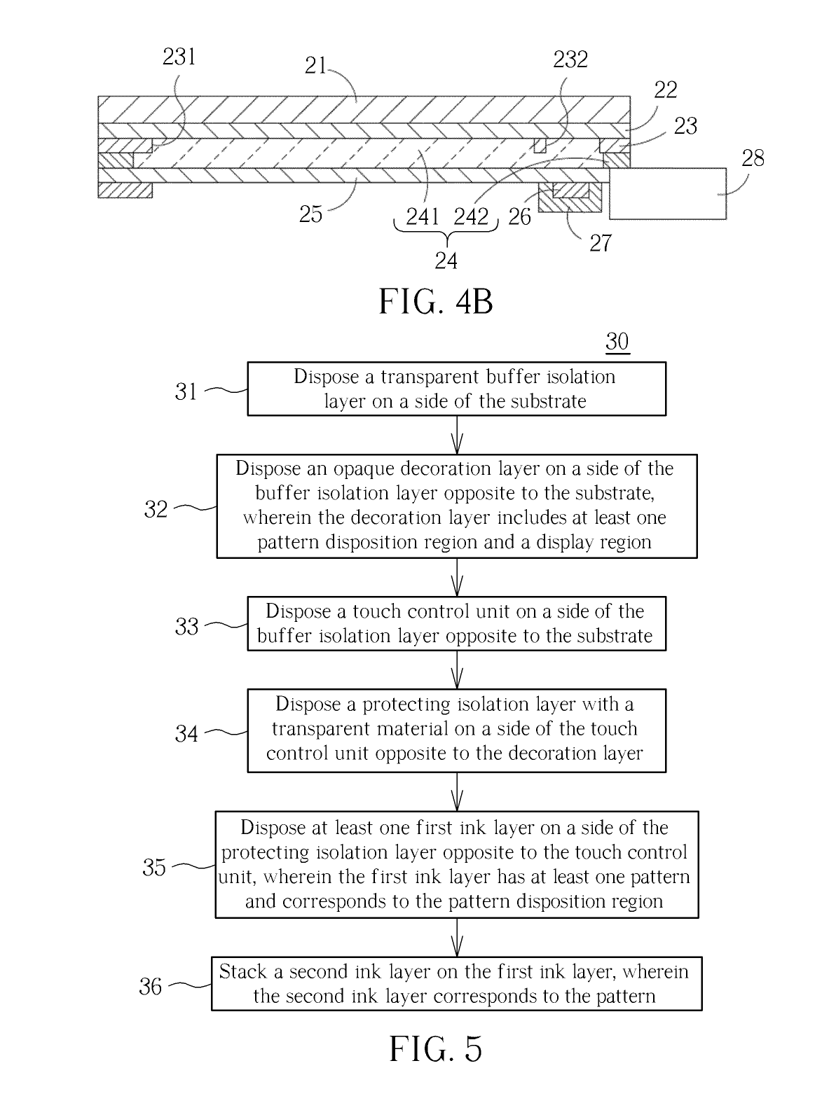

Please refer to the schematic structure of the touch panel of an embodiment of the present invention shown in FIG. 3 and FIG. 4A and the process flow of the related fabrication method shown in FIG. 5. The touch panel 20 includes a substrate 21, a buffer isolation layer 22, a decoration layer 23, a touch unit 24, a protecting isolation layer 25, a first ink layer 26 and a second ink layer 27. The fabrication process 30 of the touch panel 20 includes the following steps:

Step 31: Disposing a transparent buffer isolation layer 22 on a side of the transparent substrate 21, wherein the substrate 21 can be transparent glass, color filter, plastic substrate or polarizer, and the buffer isolation layer 22 can be made of SiO₂ so as to improve the adhesion of the touch unit 24.

Step 32: Disposing an opaque decoration layer 23 on a side of the buffer isolation layer 22 opposite to the substrate 21, wherein the decoration layer 23 can be made of black resin or photoresist, and has at least one pattern disposition region 232 and a display region 231 defined therein. There are various formation methods of the display region 231 and pattern disposition region 232. Currently, the photomask formation method is widely adopted by manufacturer for forming the display region 231 and pattern disposition region 232. The number of the pattern disposition region 232 is not limited and may be designed based on practical requirement. In this embodiment, there are four pattern disposition regions 232.

Step 33: Disposing a touch unit 24 on a side of the buffer isolation layer 22 opposite to the substrate 21, wherein the above-mentioned decoration layer 23 is sandwiched between the touch unit 24 and the buffer isolation layer 22, and the touch unit 24 is composed of a transparent sensing unit 241 and a plurality of wirings 242. The touch unit 24 is electrically connected to a circuit board 28. The transparent sensing unit 241 corresponds to the display region 231 of the decoration layer 23, and extends over the pattern disposition region 232 such that the pattern disposition region 232 may have a touch sensing function. The wirings 242 correspond to the decoration layer 23.

Step 34: Disposing a protecting isolation layer 25 made of transparent material on a side of the touch unit 24 opposite to the decoration layer 23, serving as a protecting layer of the touch unit 24, wherein the protecting isolation layer 25 can be made of SiO₂.

Step 35: Disposing at least one first ink layer 26 on a side of the protecting isolation layer 25 opposite to the touch unit 24. The hollowing first ink layer 26 defines at least one pattern 261, and corresponds to the pattern disposition region 232. Each pattern 261 has a relatively smaller area than that of each pattern disposition region 232 for being disposed therein and providing a larger shift tolerance of the pattern 261.

Step 36: Stacking a second ink layer 27 on the first ink layer 26. The second ink layer 27 corresponds to the pattern 261 (the white portion represented by the pattern 261 in FIG. 3). The second ink layer 27 may have four regions with small areas respectively, corresponding to four patterns 261, and may optionally have a whole region with a large area to completely cover all the patterns 261. The color of the second ink layer 27 is different from the color of the first ink layer 26. For example, the first ink layer 26 is black, and the second ink layer 27 is white, red, yellow, green, or blue, so as to make the patterns 261 have a same color or different colors. However, the second ink layer 27 may be omitted based on a practical requirement. In addition, the first ink layer 26 and the second ink layer 27 may also be disposed as FIG. 4B, wherein the patterns 261 are formed by the first ink layer 26 and then the second ink layer 27 are stacked on the first ink layer 26.

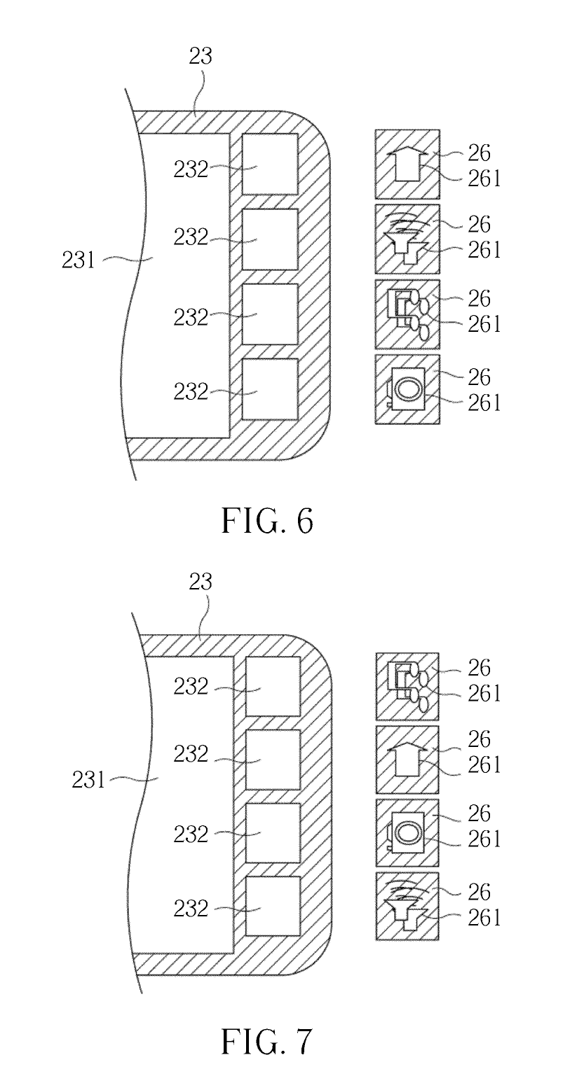

With respect to the configuration and relative position of the first ink layer 26 and the decoration layer 23, please refer to FIG. 6 together with FIG. 3 for further explanation. The embodiment of FIG. 3 and FIG. 6 has four pattern disposition regions 232 and four corresponding first ink layers 26, each of which corresponds to a pattern disposition region 232. Each first ink layer 26 has a pattern 261, and each pattern disposition region 232 is capable of containing the corresponding pattern 261. The area of the first ink layer 26 is greater than the area of the pattern disposition region 232. Accordingly, each pattern 261 can be completely shown in the pattern disposition region 232 when disposing the first ink layer 26 below the corresponding pattern disposition region 232, as shown in FIG. 3. When the first ink layers 26 and the decoration layer 23 have the same color, such as both of them are black, the display effect on the substrate 21 is the same as the pattern formed on the decoration layer 23 by the conventional photomask formation process. According to the present invention, since the patterns 261 are disposed in the first ink layer 26 and the pattern disposition regions 232 of the decoration layer 23 present as hollow frames, the locations of the patterns 261 can be varied optionally. As shown in FIG. FIG. 7, the locations of the patterns 261 of FIG. 7 are different from the locations of the patterns 261 in FIG. 3. If the patterns 261 are required to be replaced by other patterns, the manufacturer only needs to change the first ink layer 26, without changing or modifying the decoration layer 23. In other words, according to the present invention, the photomask formation process is only used for forming the hollow frame-shaped pattern disposition regions 232 in the decoration layer 23, and to alter the pattern only by the first ink layer 26. The first ink layer 26 is formed by ink printing process with simple formation method and low cost compared with photomask formation process such that the fabrication cost and the productive hours can be reduced. Therefore, the fabrication period of the touch panel can be reduced. It should be noted that there will no drop height or bounding edge exists around the patterns 261 because the decoration layer 23 and the first ink layer 26 have identical color and small thicknesses, even though the pattern disposition regions 232 are frame-shaped and the decoration layer 23 partially overlaps the first ink layer 26. The drawing presents the bounding edges of the pattern disposition regions 232 only for illustrating the region thereof.

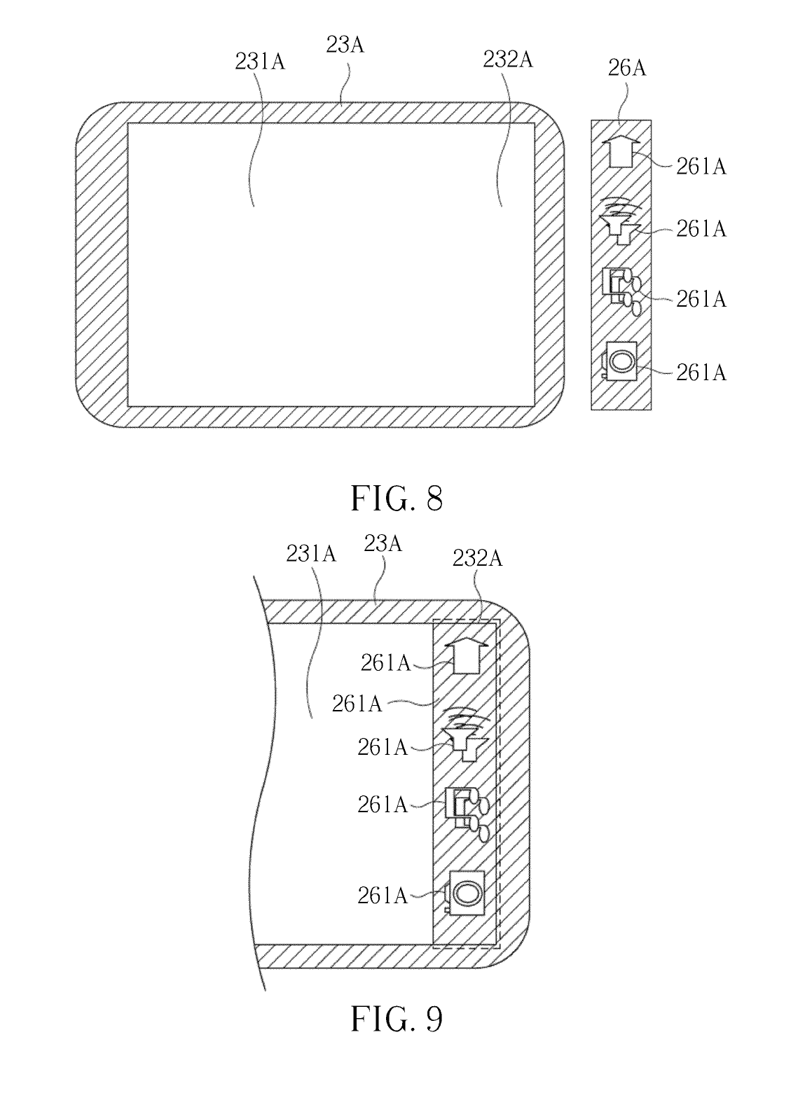

Please refer to the embodiment shown in FIG. 8 and FIG. 9. The decoration layer 23A has a display region 231A and a pattern disposition region 232A. The display region 231A is connected to the pattern disposition region 232A, such that the decoration layer 23A has a rectangular shape. The pattern disposition region 232A corresponds to a first ink layer 26A with a large area and four patterns 261A. Accordingly, only the first ink layer 26A needs to be changed when altering the patterns.

In addition, the pattern 261/261A is not limited to the type shown in the figures. In an alternate embodiment, the type of the pattern may be, but is not limited to, a text (such as a letter, trademark, logo or Arabic number) or a symbol (such as icon, graphics, geometric conformation or a hole).

In conclusion, the present invention provides a touch panel structure and related fabrication method with a delaminated structure and related process to form the touch panel pattern, so as to reduce the fabrication cost and productive hours.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A touch panel structure, comprising:
a substrate, made of a transparent material;
a decoration layer, disposed on a side of the substrate, comprising at least one pattern disposition region and a display region and made of an opaque material;
a touch unit, disposed on a side of the substrate and comprising a transparent sensing unit, wherein the decoration layer is sandwiched between the touch unit and the substrate, and the transparent sensing unit extends over the pattern disposition region; and
at least one first ink layer, disposed on the touch unit, comprising at least one pattern and corresponding to the pattern disposition region.

2. The touch panel structure of claim 1, further comprising a second ink layer stacked on the first ink layer and corresponding to the pattern.

3. The touch panel structure of claim 2, wherein a color of the second ink layer is different from a color of the first ink layer.

4. The touch panel structure of claim 1, further comprising a buffer isolation layer and a protecting isolation layer, wherein the buffer isolation layer is disposed between the substrate and the touch unit, the protecting isolation layer is disposed on a side of the touch unit opposite to the decoration layer, and the buffer isolation layer and the protecting isolation layer are made of a transparent material respectively.

5. The touch panel structure of claim 1, wherein a color of the first ink layer is identical to a color of the decoration layer.

6. The touch panel structure of claim 1, wherein the touch unit further comprises a plurality of wirings corresponding to the decoration layer.

7. The touch panel structure of claim 1, wherein the pattern comprises text and symbol.

8. The touch panel structure of claim 1, wherein the at least one pattern comprises a first area, the at least one pattern disposition region comprises a second area, and the first area is smaller than the corresponding second area.

9. A fabrication method of a touch panel structure, comprising :
disposing an opaque decoration layer on a side of a substrate made of a transparent material to define a display region and at least one pattern disposition region;
disposing a touch unit on a side of the substrate, wherein the decoration layer is sandwiched between the touch unit and the substrate, and the touch unit comprises a transparent sensing unit extending over the pattern disposition region; and
disposing at least one first ink layer on the touch unit, wherein the first ink layer comprises at least one pattern and corresponds to the pattern disposition region.

10. The fabrication method of the touch panel structure of claim 9, further comprising stacking a second ink layer on the first ink layer after the step of disposing the first ink layer, wherein the second ink layer corresponds to the pattern.

11. The fabrication method of the touch panel structure of claim 9, further comprising disposing a transparent buffer isolation layer between the substrate and the touch unit, and disposing a transparent protecting isolation layer on a side of the touch unit opposite to the decoration layer.
